(19) United States
(12) Patent Application Publication
(10) Pub. No.: US 2009/0159959 A1
(43) Pub. Date: Jun. 25, 2009

(54) Nonvolatile semiconductor memory device and method of fabricating the same

(75) Inventors: Jin-Taek Park, Hwasung-City (KR); Jungdal Choi, Seoul-City (KR)

Correspondence Address: MILLS & ONELLO LLP, ELEVEN BEACON STREET, SUITE 605, BOSTON, MA, 02108, US

(73) Assignee: Samsung Electronics Co., Ltd., Gyeonggi-do (KR)

(21) Appl. No.: 12/291,449

(22) Filed: Nov. 10, 2008

(30) Foreign Application Priority Data
Dec. 21, 2007 (KR) 10-2007-0135386

(51) Int. Cl. H01L 29/792

(52) U.S. Cl. 257/324; 257/E29.309

(57) ABSTRACT

A charge trap flash (CTF) memory cell and manufacturing method include a semiconductor substrate and an isolation region and an active region being formed in the substrate. A tunneling layer, a charge trapping layer and a blocking layer are formed on the isolation region and the active region. A resistance layer is formed on the blocking layer over the isolation region. The resistance layer prevents or substantially reduces trapping of electrons at the edges of the active region, i.e., the edge effect. As a result, after programming of the devices, the threshold voltages of the programmed cells are substantially uniform throughout the cells. This results in improved reliability of the devices.

### RELATED APPLICATION

This application claims priority to Korean Patent Application number 10-2007-0135386, filed in the Korean Intellectual Property Office on Dec. 21, 2007, the entire contents of which are incorporated herein by reference.

### BACKGROUND OF THE INVENTION

1. Field of the Invention

This application relates to semiconductor memory devices and methods of manufacturing semiconductor memory devices. In particular, this application relates to a charge trap flash (CTF) memory cell with an edge SANOS (silicon-aluminum oxide-nitride-oxide-silicon) structure and a method of manufacturing the CTF memory cell.

2. Discussion of the Related Art

Semiconductor memory devices are widely used to store data in electronic systems. Memory devices are generally classified as either volatile or non-volatile devices. Volatile memory devices lose their stored data when power to the devices is interrupted or discontinued. Non-volatile memory devices retain their data when power is removed.

Non-volatile memory devices include floating-gate type non-volatile memory devices and floating-trap type non-volatile memory devices. In a floating-gate type non-volatile memory device, a floating gate is disposed between a semiconductor substrate and a control gate, the floating gate and the substrate being separated by a tunneling insulation film. A data bit is programmed to the device by storing an electric charge in the floating gate. The floating-trap memory device programs a data bit by storing charges in a trap that is formed within a non-conductive charge storage film between a semiconductor substrate and a gate electrode.

A typical floating-trap memory structure is referred to as a silicon-oxide-nitride-oxide-silicon (SONOS) cell structure. The SONOS structure includes a channel region formed of a silicon substrate, a tunneling layer formed of a first oxide film, a charge storage film formed of a nitride film, a blocking layer formed of a second oxide film, and a control gate electrode formed of a conductive film. The charge storage film may be made of a silicon nitride film or a high-dielectric material film.

FIG. 1 contains a schematic plan view of a memory device using a conventional floating-trap memory structure. FIG. 2 contains three schematic cross-sectional views of the floating-trap memory structure of FIG. 1. The three schematic cross-sectional views of FIG. 2, from left to right in the figure, are taken along lines I-I′, II-II′ and III-III′, respectively, of FIG. 1.

Referring to FIGS. 1 and 2, the memory cell region of the semiconductor device includes a plurality of word lines WL extending in parallel and crossing a plurality of active regions 15 extending in parallel at a perpendicular angle. The active regions 15 are defined and separated by silicon trench isolation (STI) regions 18 formed in trenches 13. The device includes a gate stack formed on the semiconductor substrate 10. The gate stack includes a tunneling insulation layer 21 formed over the STI regions 18 and the active regions 15. A charge trapping layer 23 is formed over the tunneling insulation layer 21. A blocking dielectric layer 25 is formed over the charge trapping layer 23. A gate in the form of conductive lines 42 is formed over the structure. Source and drain regions 51 are formed on opposite sides of the conductive gates. Device active regions are defined between the source and drain regions 51 under the conductive gates 42.

During operations such as cell programming operations, a voltage is applied to the memory cells, such as at the conductive gate. In the conventional device shown in FIGS. 1 and 2, during programming, some electrons may migrate laterally toward the edges of the active regions 15 and are trapped at the edges of the active regions 15, as shown by the arrow 7 in FIG. 2. This results in a non-uniform electric field being created in the device, that is, the electric field is higher at the edge of the active region than at other parts of the active region. This is commonly referred to as the “edge effect,” in which non-uniform collections of trapped electrons at edges of the active regions cause interference between cells and degrade the operation of the device. As a result of the edge effect in which the uneven trapping of electrons occurs, devices in the programmed device have non-uniform threshold voltages Vth. Errors may occur during the programming of cells. This results in a degradation of the overall operation of the memory device.

### SUMMARY OF THE INVENTION

The invention provides a memory cell structure and method of manufacturing the memory cell structure in which the trapping of electrons at the edges of the active region, i.e., the edge effect, is substantially reduced or eliminated. As a result, after programming of the devices, the threshold voltages of the programmed cells are substantially uniform throughout the cells. This results in improved reliability of the devices.

According to a first aspect, the present invention is directed to a semiconductor memory device. The semiconductor memory device includes a substrate, an isolation region formed in the substrate and an active region formed in the substrate adjacent to the isolation region. A tunneling layer is formed on the active region and the isolation region. A charge trapping layer is formed on the tunneling layer. A blocking layer is formed on the charge trapping layer. A resistance layer is formed on the blocking layer over the isolation region.

In one embodiment, the resistance layer comprises polysilicon.

In one embodiment, the resistance layer comprises a substantially flat top surface.

In one embodiment, the resistance layer comprises a substantially curved bottom surface.

In one embodiment, the resistance layer is an island type with multiple resistance layers over the isolation region.

In one embodiment, a top surface of resistance layer has a height higher than a height of the blocking layer.

In one embodiment, the resistance layer is a non-metal resistance layer.

According to another aspect, the present invention is directed to a method of making a semiconductor memory device. According to the method, an isolation region is formed in a substrate. An active region is formed in the substrate adjacent to the isolation region. A tunneling layer is formed on the active region and the isolation region. A charge trapping layer is formed on the tunneling layer. A blocking layer is formed on the charge trapping layer. A resistance layer is formed on the blocking layer over the isolation region.

In one embodiment, the resistance layer is formed with polysilicon.

In one embodiment, the resistance layer is formed with a substantially flat top surface.

In one embodiment, the resistance layer is formed with a substantially curved bottom surface.

In one embodiment, the resistance layer is formed as an island type with multiple resistance layers over the isolation region.

In one embodiment, a top surface of the resistance layer is formed to have a height greater than a height of the blocking layer.

In one embodiment, the resistance layer is a non-metal resistance layer.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 contains a schematic plan view of a memory device using a conventional floating-trap memory structure.

FIG. 2 contains three schematic cross-sectional views of the floating-trap memory structure of FIG. 1. The three schematic cross-sectional views of FIG. 2, from left to right in the figure, are taken along lines I-I′, II-II′ and III-III′, respectively, of FIG. 1.

FIG. 3 contains a schematic plan view of a memory device using a floating-trap memory structure with a resistance pattern or layer according to the present invention.

FIG. 4 contains three schematic cross-sectional views of the floating-trap memory structure of FIG. 3, according to one embodiment of the invention. The three schematic cross-sectional views of FIG. 4, from left to right in the figure, are taken along lines I-I′, II-II′ and III-III′, respectively, of FIG. 3.

FIG. 5 contains three schematic cross-sectional views of the floating-trap memory structure of FIG. 3, according to another embodiment of the invention. The three schematic cross-sectional views of FIG. 5, from left to right in the figure, are taken along lines I-I′, II-II′ and III-III′, respectively, of FIG. 3.

FIG. 6 contains three schematic cross-sectional views of the floating-trap memory structure of FIG. 3, according to another embodiment of the invention. The three schematic cross-sectional views of FIG. 6, from left to right in the figure, are taken along lines I-I′, II-II′ and III-III′, respectively, of FIG. 3.

FIG. 7 contains three schematic cross-sectional views of the floating-trap memory structure of FIG. 3, according to another embodiment of the invention. The three schematic cross-sectional views of FIG. 7, from left to right in the figure, are taken along lines I-I′, II-II′ and III-III′, respectively, of FIG. 3.

FIG. 8 contains three schematic cross-sectional views of the floating-trap memory structure of FIG. 3, according to another embodiment of the invention. The three schematic cross-sectional views of FIG. 8, from left to right in the figure, are taken along lines I-I′, II-II′ and III-III′, respectively, of FIG. 3.

FIGS. 9A and 9B are detailed, enlarged cross-sectional views of the floating-trap memory structure of FIG. 3, taken along line I-I′ only of FIG. 3.

FIGS. 10-36 each contain three schematic cross-sectional views illustrating steps in methods of manufacturing the floating-trap memory structures of FIGS. 3-8, according to embodiments of the invention. The three schematic cross-sectional views of FIGS. 10-36, from left to right in the figures, are taken along lines I-I′, II-II′ and III-III′, respectively, of FIG. 3.

FIG. 37 is a schematic block diagram of a nonvolatile memory device in accordance with embodiments of the present invention.

FIG. 38 is a schematic block diagram of a system including a semiconductor memory device in accordance with embodiments of the present invention.

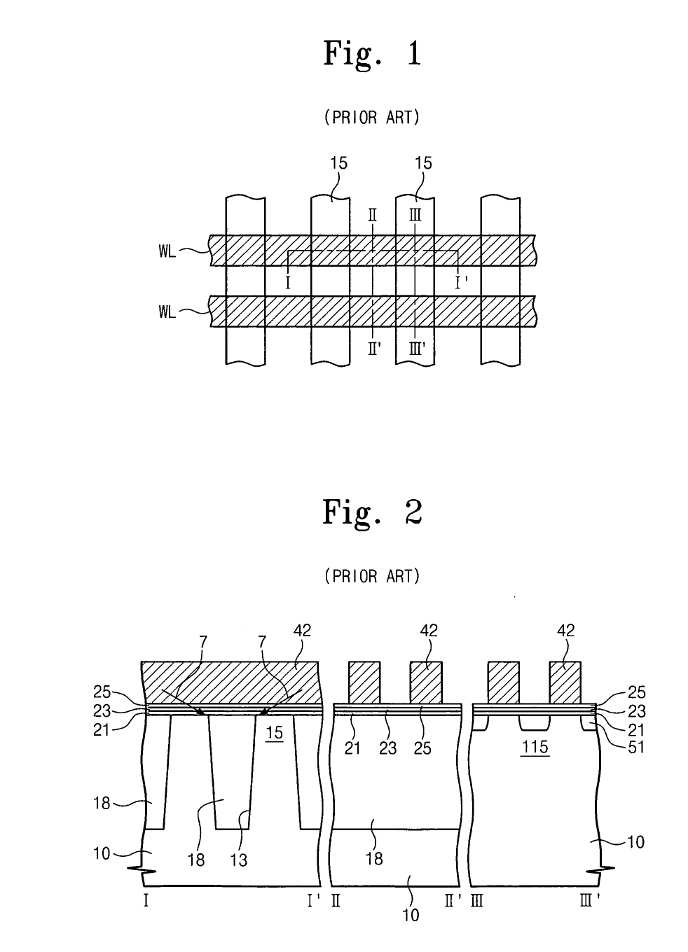

### DETAILED DESCRIPTION OF PREFERRED EMBODIMENTS

According to the invention, the trapping of electrons at the edge of the active region of memory cells is substantially reduced or eliminated. This is realized by including a resistance region, layer or pattern over the blocking layer and the STI, but not over the active region. The resistance layer blocks the lateral or oblique flow of electrons, as shown by the arrows 7 in FIG. 2 for conventional devices, such that, in the device of the invention, electrons are not non-uniformly trapped at the edge of the active region. Threshold voltages of cells are uniform, resulting in improved operational characteristics and reliability of the devices.

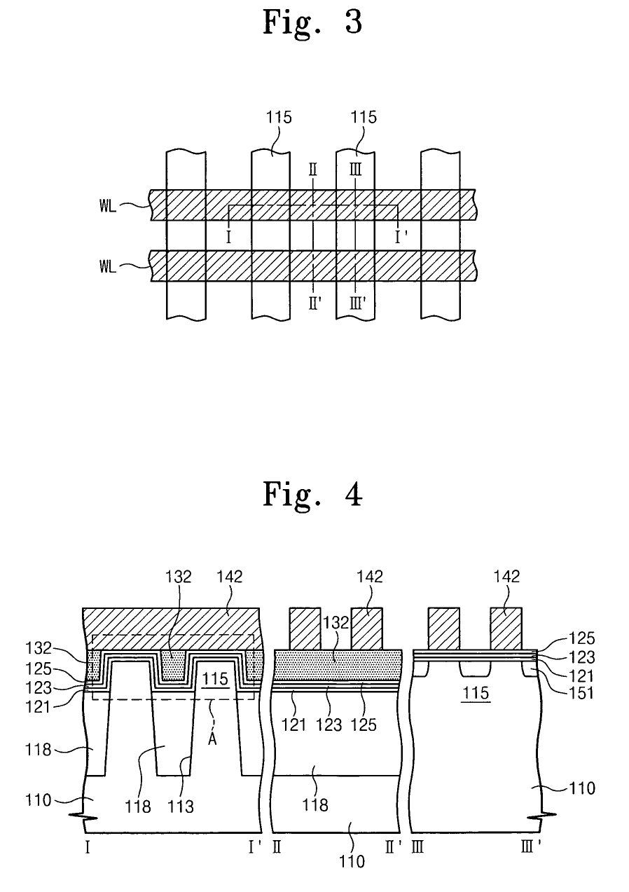

FIG. 3 contains a schematic plan view of a memory device using a floating-trap memory structure with a resistance pattern or layer according to the present invention. FIG. 4 contains three schematic cross-sectional views of the floating-trap memory structure of FIG. 3, according to one embodiment of the invention. The three schematic cross-sectional views of FIG. 4, from left to right in the figure, are taken along lines I-I′, II-II′ and III-III′, respectively, of FIG. 3.

Referring to FIGS. 3 and 4, the memory cell region of the semiconductor device includes a plurality of word lines WL extending in parallel and crossing a plurality of active regions 115 extending in parallel at an angle perpendicular to the word lines. The active regions 115 are defined and separated by silicon trench isolation (STI) regions 118 in trenches 113. The device includes a gate stack formed on the semiconductor substrate 110. The gate stack includes a first dielectric layer or tunneling insulation layer 121 formed over the STI regions 118 and the active regions 115. The tunneling insulation layer 121 can be formed of, for example, SiO₂.

A charge trapping layer 123 is formed over the tunneling insulation layer 121. The charge trapping layer 123 can be formed of, for example, Si₃N₄, SiON, Al₂O₃, HfO₂, HfAlO, HfSiO.

A second dielectric layer or blocking dielectric layer 125 is formed over the charge trapping layer 123. The blocking dielectric layer 125 can be formed of, for example, Al₂O₃, HfO₂, Hafnium aluminate:Hf₁₋ₓAlO_{y}, Hafnium silicate:HfₓSi₁₋ₓO₂, Hf—Si-oxynitride, ZrO₂, Zr-Silicate:ZrₓSi₁₋ₓO₂, Zr—Si-oxynitride or a composite film including a combination of the above high-dielectric materials.

A gate in the form of conductive line 142 is formed over the structure. The gate conductive line 142 can be formed of metal, for example, W. Source and drain regions 151 are formed on opposite sides of the conductive gates. Device active regions are defined between the source and drain regions 151 under the conductive gates 142.

In accordance with the invention, the structure of FIG. 4 also includes a resistance region, layer or pattern 132. The resistance layer 132 is formed within a trench at the top of the STI region 118. The tunneling insulation layer 121, the charge trapping layer 123 and the blocking dielectric layer 125 are recessed and are also formed within the trench and conform to the trench. In one embodiment, the resistance layer 132 is formed of polysilicon. It is noted that the top surface of the resistance layer 132 is substantially even with or at the substantially the same vertical height as the top surface of the blocking layer 125.

The resistance pattern 132 has a resistance that is higher than the resistance of the metal layer 142. As a result, the resistance pattern 132 reduces the number of electrons trapped at the edge of the active region 115. Thus, the threshold voltages of the cells are more uniform, and interference between cells is reduced. The reliability of the device is greatly improved.

The resistance pattern 132 is described above as being formed of polysilicon. It is noted that a resistance pattern 132 with a resistance higher than that of the metal layer 142 will reduce the number of electrons being trapped at the edge of the active region and, therefore, reduce the interference between cells.

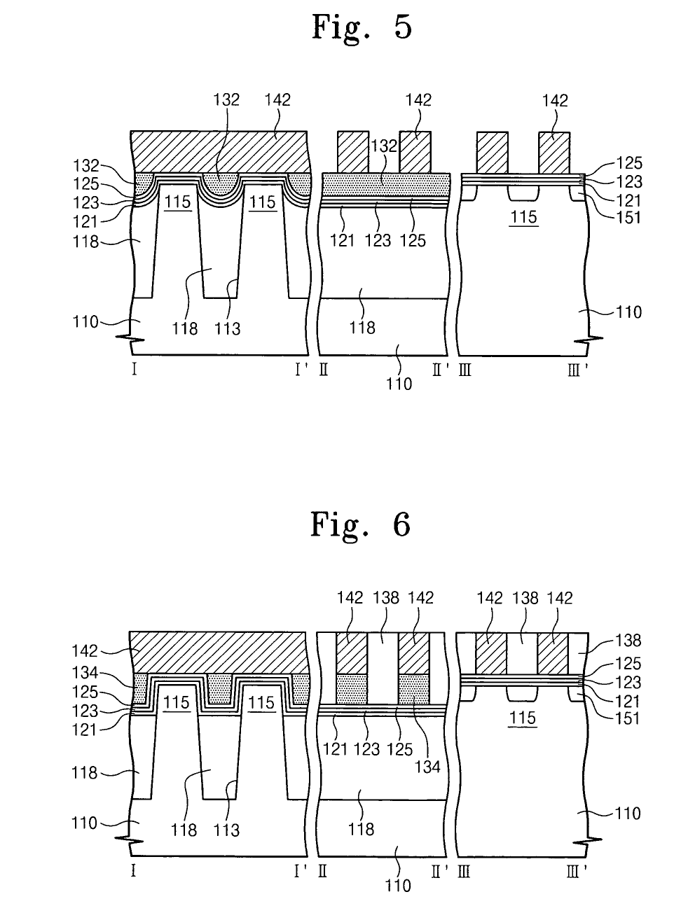

FIG. 5 contains three schematic cross-sectional views of the floating-trap memory structure of FIG. 3, according to another embodiment of the invention. The three schematic cross-sectional views of FIG. 5, from left to right in the figure, are taken along lines I-I′, II-II′ and III-III′, respectively, of FIG. 3.

The embodiment of FIG. 5 is different than the embodiment of FIG. 4 in that the resistance pattern 132 of the embodiment of FIG. 5 has a curved bottom surface. It is noted that the top surface of the resistance layer 132 is substantially even with or at the substantially the same vertical height as the top surface of the blocking layer 125. Description of elements in the embodiment of FIG. 5 that are substantially the same as elements of the embodiment of FIG. 4 will not be repeated.

FIG. 6 contains three schematic cross-sectional views of the floating-trap memory structure of FIG. 3, according to another embodiment of the invention. The three schematic cross-sectional views of FIG. 6, from left to right in the figure, are taken along lines I-I′, II-II′ and III-III′, respectively, of FIG. 3.

The embodiment of FIG. 6 is different than the embodiments of FIGS. 4 and 5 in that the resistance pattern 132 of the embodiment of FIG. 6 has an “island” configuration instead of the elongated configuration of the embodiments of FIGS. 4 and 5. Referring to the middle view of FIG. 6 taken along line II-II′ of FIG. 3, the resistance pattern 132 is formed only at the region of the intersection of the STI 118 and the conductive line 142. The structure of FIG. 6 also includes an interlayer dielectric (ILD) layer 138 between the conductive lines 142 and the “island” type portions of the resistance pattern 132. It is noted that the top surface of the resistance pattern 132 is substantially even with or at the substantially the same vertical height as the top surface of the blocking layer 125. Description of elements in the embodiment of FIG. 6 that are substantially the same as elements of the embodiments of FIGS. 4 and/or 5 will not be repeated.

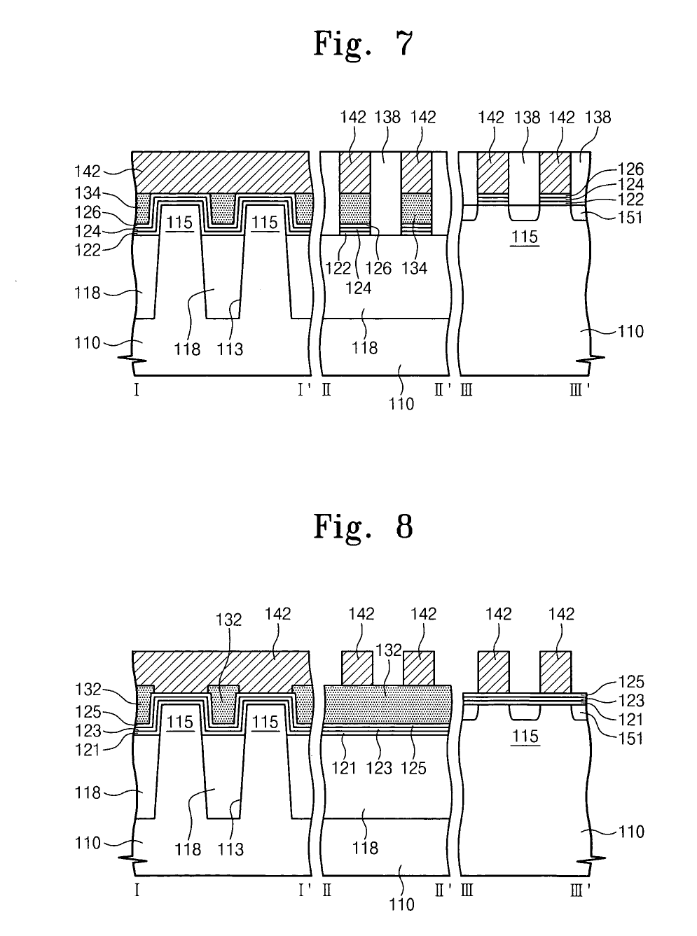

FIG. 7 contains three schematic cross-sectional views of the floating-trap memory structure of FIG. 3, according to another embodiment of the invention. The three schematic cross-sectional views of FIG. 7, from left to right in the figure, are taken along lines I-I′, II-II′ and III-III′, respectively, of FIG. 3.

The embodiment of FIG. 7 is different than the embodiments of FIGS. 4, 5 and 6 in that the resistance pattern 132 of the embodiment of FIG. 7 and the three layers between the resistance pattern 132 have an “island” configuration, similar to the island configuration of the resistance layer 132 of the embodiment of FIG. 6, instead of the elongated configuration of the embodiments of FIGS. 4 and 5. That is, in the embodiment of FIG. 7, not only is the resistance pattern 132 patterned into an island configuration, but the tunneling layer 122, the charge trapping layer 124 and the blocking layer 126 are also patterned into an “island” configuration. Referring to the middle view of FIG. 7 taken along line II-II′ of FIG. 3, the layers 122, 124 and 126, as well as the resistance pattern 132, are formed only at the region of the intersection of the STI 118 and the conductive line 142. The structure of FIG. 7 also includes an interlayer dielectric (ILD) layer 138 between the conductive lines 142 and the “island” type portions of the resistance pattern 132 and the layers 122, 124 and 126. It is noted that the top surface of the resistance pattern 132 is substantially even with or at the substantially the same vertical height as the top surface of the blocking layer 125. Description of elements in the embodiment of FIG. 7 that are substantially the same as elements of the embodiments of FIGS. 4, 5 and/or 6 will not be repeated.

FIG. 8 contains three schematic cross-sectional views of the floating-trap memory structure of FIG. 3, according to another embodiment of the invention. The three schematic cross-sectional views of FIG. 8, from left to right in the figure, are taken along lines I-I′, II-II′ and III-III′, respectively, of FIG. 3.

The embodiment of FIG. 8 is different than the embodiments of FIGS. 4, 5, 6 and 7 in that the resistance pattern 132 of the embodiment of FIG. 8 extends above the top surface of the blocking layer 125. That is, in the embodiment of FIG. 8, the top surface of the resistance pattern 132 is higher than the top surface of the blocking layer 125. Description of elements in the embodiment of FIG. 8 that are substantially the same as elements of the embodiments of FIGS. 4, 5, 6 and/or 7 will not be repeated.

It should be noted that various permutations and combinations of the above-described embodiments may be made in accordance with the invention. For example, the curved resistance pattern 132 in the embodiment of FIG. 5 can extend above the blocking layer 125 or 126, as in the embodiment of FIG. 8. Similarly, the “island” type configurations of the resistance layer 132 can extend above the top surface of the blocking layer 125 or 126.

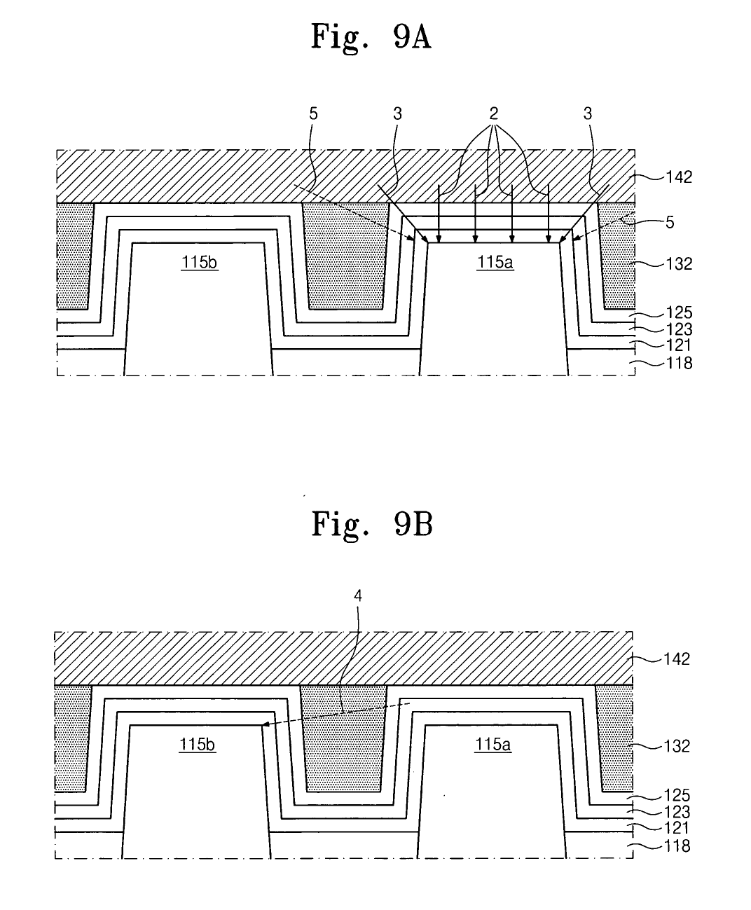

FIGS. 9A and 9B are detailed, enlarged cross-sectional views of the floating-trap memory structure of FIG. 3, taken along line I-I′ only of FIG. 3. FIGS. 9A and 9B diagrammatically illustrate the effects of the resistance pattern 132 of the invention. It is noted that FIGS. 9A and 9B illustrate the embodiment of FIGS. 4, 6 and 7. However, it is noted that this is for illustration purposes only. FIGS. 9A and 9B and the description thereof herein are applicable to all of the embodiments of the invention.

Referring to FIG. 9A, electrons can propagate to the active region 115a as indicated by vertical arrows 2 and oblique arrows 3 from the conductive line 142, through the blocking layer 125, the charge trapping layer 123 and the tunneling layer 121 to the active region 115a. However, electrons that are located more laterally in the conductive line 142 cannot reach the edge region of the active region 115a because they are blocked by the resistance pattern 132, as indicated by oblique arrows 5. As a result, these electrons are not trapped at the edge of the active region 115a, and the edge effect is eliminated. A uniform electric field is obtained.

Referring to FIG. 9B, arrow 4 indicates electrons that may propagate between adjacent active regions 115a and 115b. In accordance with the structure of the invention, these electrons from near the active region 115a are blocked by the resistance pattern 132 and, as a result, cannot be trapped at the edge of active region 115b. Hence, a uniform electric field at the active regions 115a and 115b is obtained.

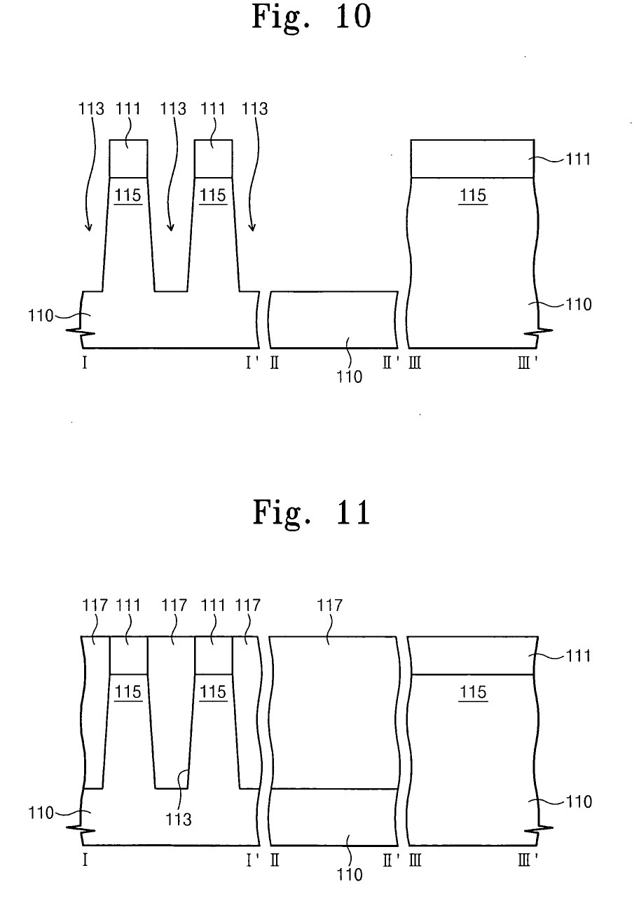

FIGS. 10-36 each contain three schematic cross-sectional views illustrating steps in methods of manufacturing the floating-trap memory structures of FIGS. 3-8, according to embodiments of the invention. The three schematic cross-sectional views of FIGS. 10-36, from left to right in the figures, are taken along lines I-I′, II-II′ and III-III′, respectively, of FIG. 3. It is noted that, throughout FIGS. 10-36, like characters refer to like elements. Accordingly, description of the formation of like elements is not repeated.

FIGS. 10-14 illustrate steps in the method of fabricating the floating-trap memory structure of FIG. 4. Referring to FIG. 10, a semiconductor substrate 110 is provided. A photoresist pattern 111 is formed on the substrate 110. Next, trenches 113 are formed such as by etching, using the photoresist pattern 111 as an etching mask.

Referring to FIG. 11, the trenches 113 are filled in with an insulating material such as undoped silicate glass (USG) or high-density plasma (HDP) oxide such that the STI defining the active regions 115 between the insulating regions 117 is formed.

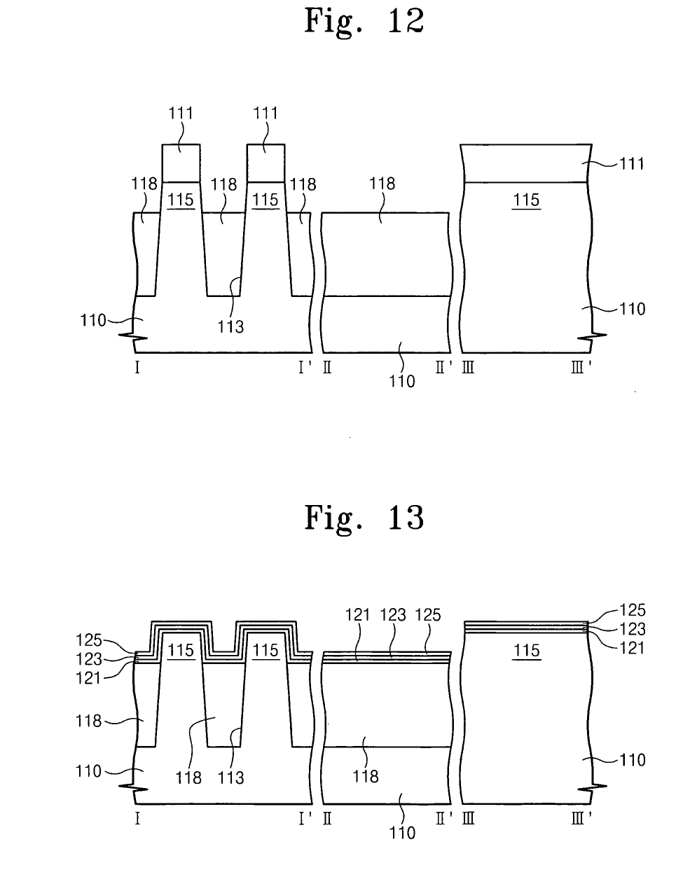

Referring to FIG. 12, the insulating regions 117 are etched, using the photoresist pattern 111 as an etching mask. As a result, the insulating regions 117 are transformed into the STI regions 118.

Referring to FIG. 13, the photoresist pattern 111 is removed. Next, the tunneling layer 121, the charge trapping layer 123 and the blocking layer 125 are sequentially formed on the structure. These layers 121, 123 and 125 are formed to conform with the shapes of the STI regions 118 and the active regions 115. Specifically, the layers 121, 123 and 125 are formed over the top surface of the STI regions 118 in the upper portion of the trenches remaining over the STI regions 118.

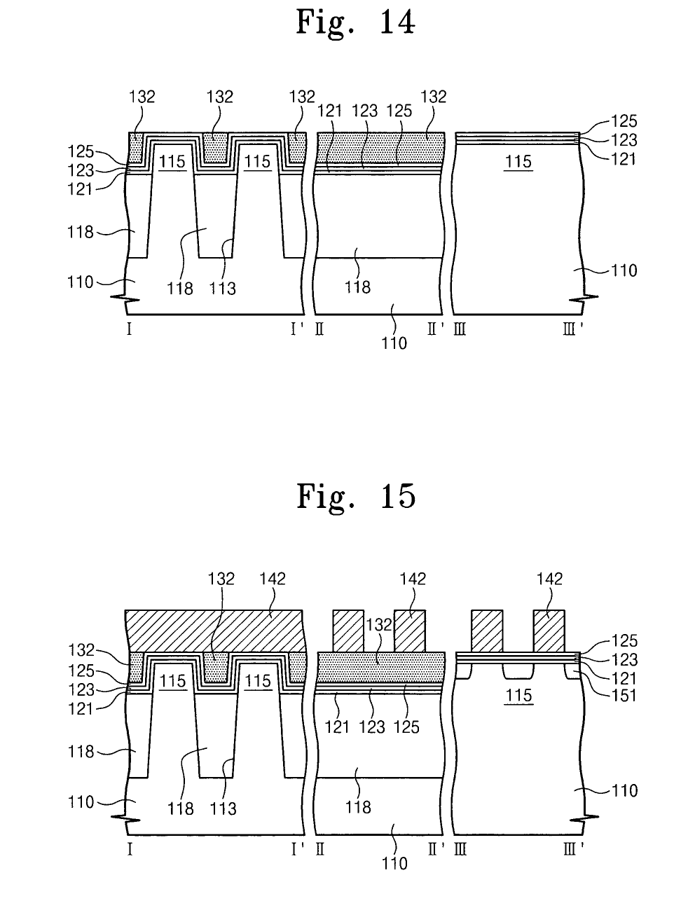

Referring to FIG. 14, next, the resistance layer or pattern 132 is formed over the layers 121, 123 and 125. The top surface of the resistance pattern 132 is made to be level with the top surface of the portion of the blocking layer 125 over the active regions 115. The resistance pattern 132 is formed over the STI layers 118. Referring to FIG. 15, next, the conductive line 142 is formed over the structure.

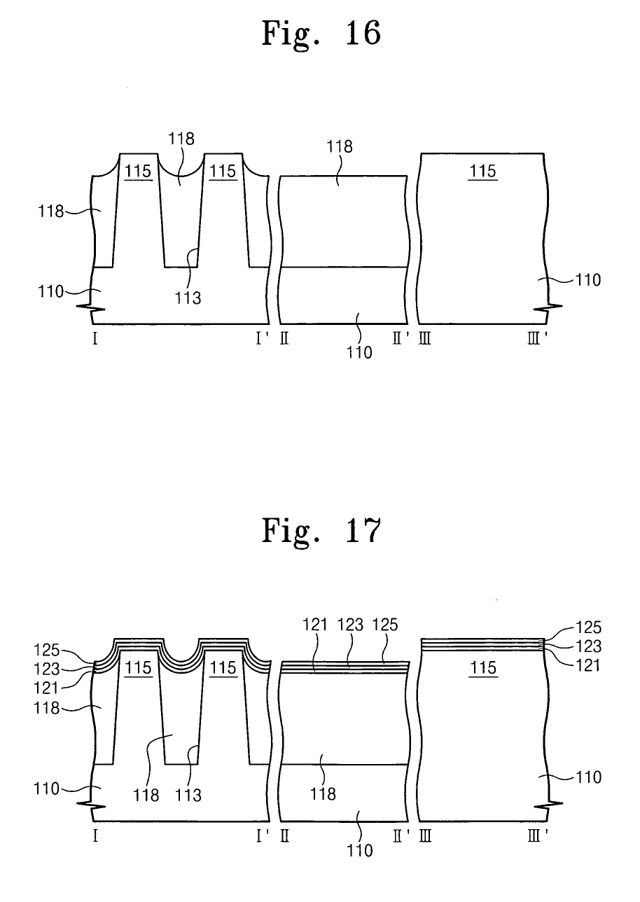

FIGS. 16-19 illustrate steps in the method of manufacturing the floating trap memory device of FIG. 5 that are different than steps shown in FIGS. 10-15. Referring to FIG. 16, following the steps of FIG. 11, the photoresist pattern 111 is removed, and the top surface of the STI regions 118 are made to be curved such as by polishing. Specifically, the etch rate of the photoresist pattern 111 is faster than that of the insulating regions 117, such that the curved STI regions are formed as a result of the polishing. Referring to FIG. 17, the three layers 121, 123 and 125 are formed over the active regions 115 and the curved STI regions 118. The layers 121, 123 and 125 conform to the active regions 115 and the STI regions 118, such that the top surfaces of the blocking layer 125 has a curved surface.

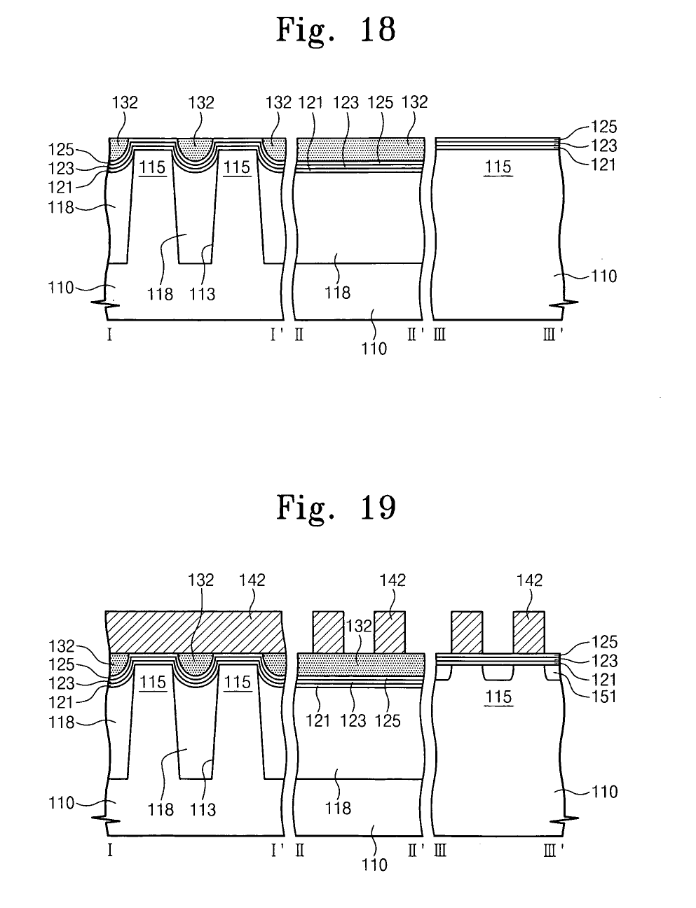

Referring to FIG. 18, next, the resistance pattern 132 is formed over the blocking layer 125. The top surface of the resistance pattern 132 is made to be even with the top surface of the blocking layer 125 over the active regions 115 such as by polishing. The bottom surface of the resistance pattern at the STI regions 118 is curved to match the curved top surface of the blocking layer 125. Referring to FIG. 19, next, the conductive pattern 142 is formed over the structure.

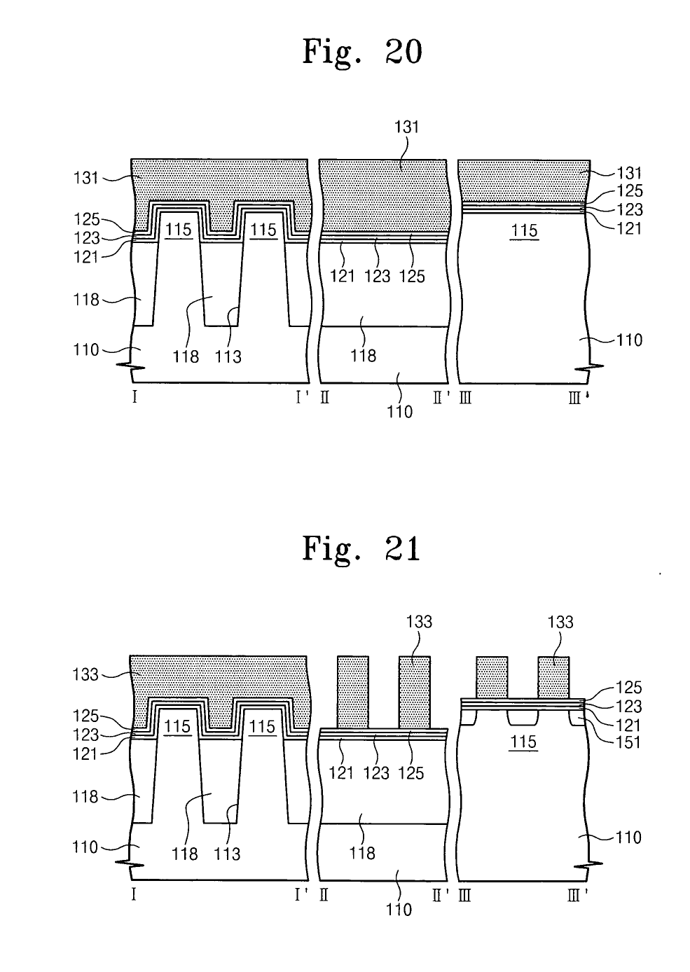

FIGS. 20-24 illustrate steps in the method of manufacturing the floating-trap memory device of FIG. 6 that are different than steps shown in FIGS. 10-15. Referring to FIG. 20, following the steps of FIG. 13, a layer 131 of the material of the resistance pattern 132, which, in one embodiment, is polysilicon, is formed over the blocking layer 125.

Referring to FIG. 21, next, the resistance material 131 is etched or polished using photolithographic masking down to the top surface of the blocking layer 125 to form the “island” configuration of the resistance pattern 132, in the form of resistance layer pillars 133 at the intersection of the STI 118 and the conductive line 142.

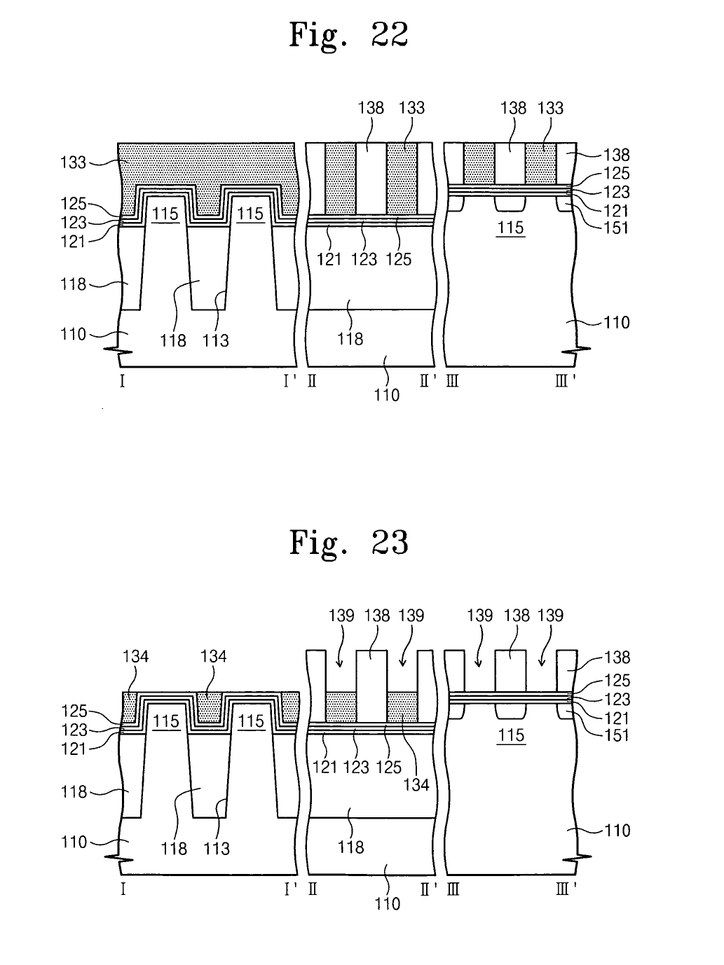

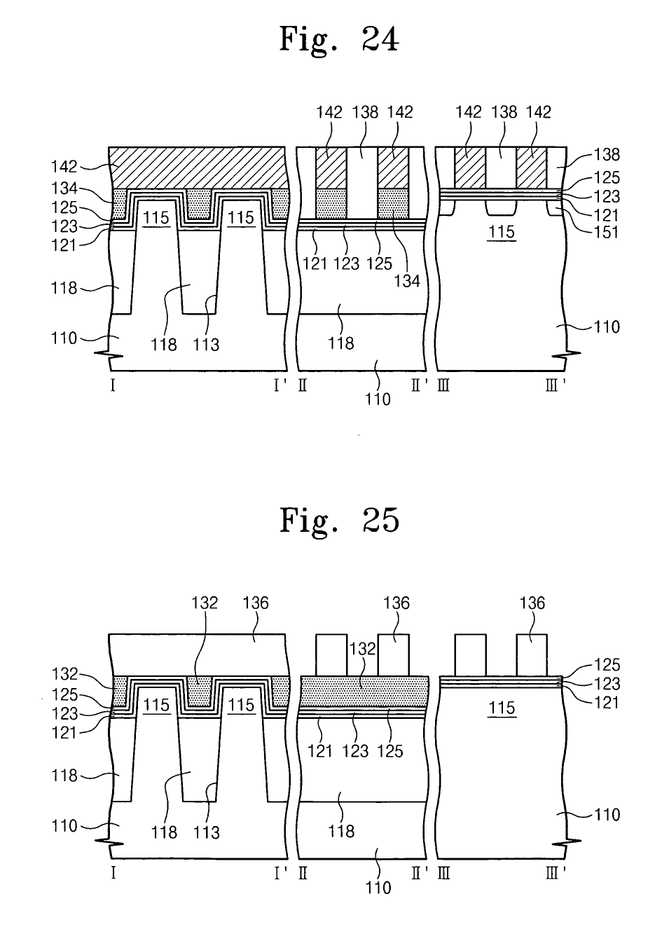

Referring to FIG. 22, next, an insulating material 138 such as an ILD material, such as Please fill in material for layer 138 is formed between the resistance layer pillars 133. Referring to FIG. 23, next, the resistance layer 133 is etched and/or polished such that its top surface is even with the top surface of the portion of the blocking layer 125 at the active regions 115 and such that the “island” type resistance pattern 134 is formed. Referring to FIG. 24, next, the conductive layer or line 142 is formed over the resistance pattern 134 having the “island” configuration.

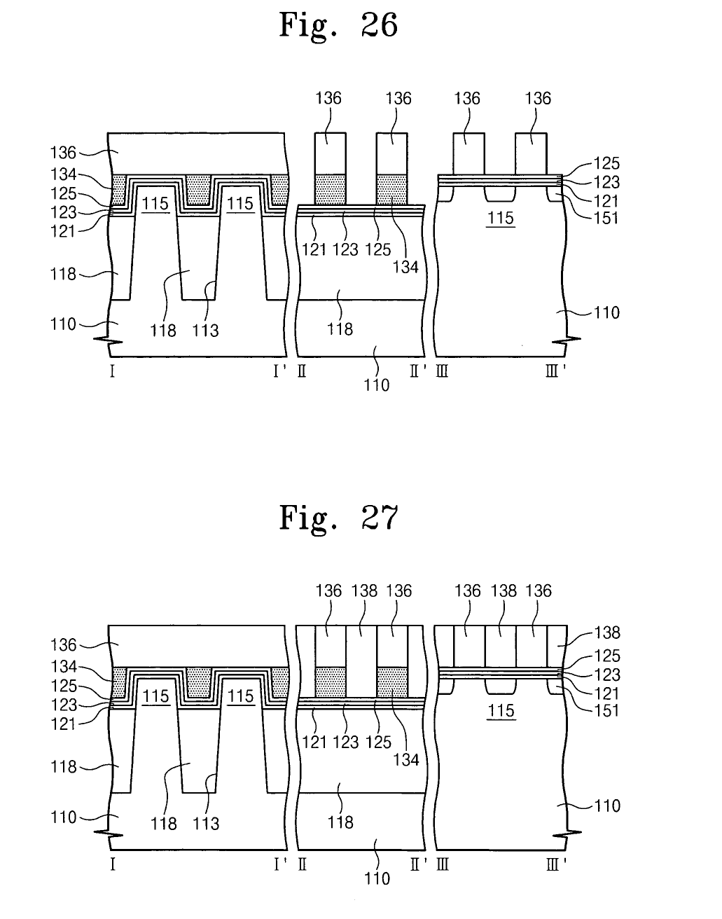

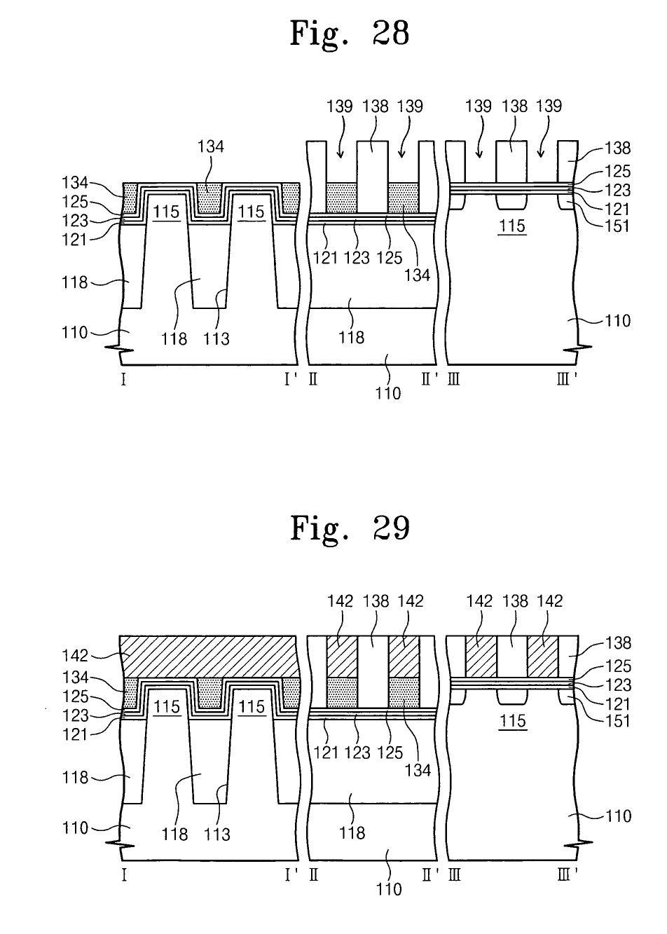

FIGS. 25-29 illustrate steps of an alternative method of manufacturing the floating-trap memory device of FIG. 6 that are different than steps shown in FIGS. 10-15 and FIGS. 20-24. Referring to FIG. 25, following the steps of FIG. 14, a photoresist pattern 136 is formed over the resistance layer 132. Referring to FIG. 26, next, the resistance layer 132 is etched using the photoresist pattern 136 as an etching mask to form the “island” type resistance pattern 134. Referring to FIG. 27, next, the ILD pattern 138 is formed between the resistance patterns 134 covered by the photoresist patterns 136. Referring to FIG. 28, next, the photoresist pattern 136 is removed. Referring to FIG. 29, next, the conductive layer or line 142 is formed over the resistance pattern 134 having the “island” configuration.

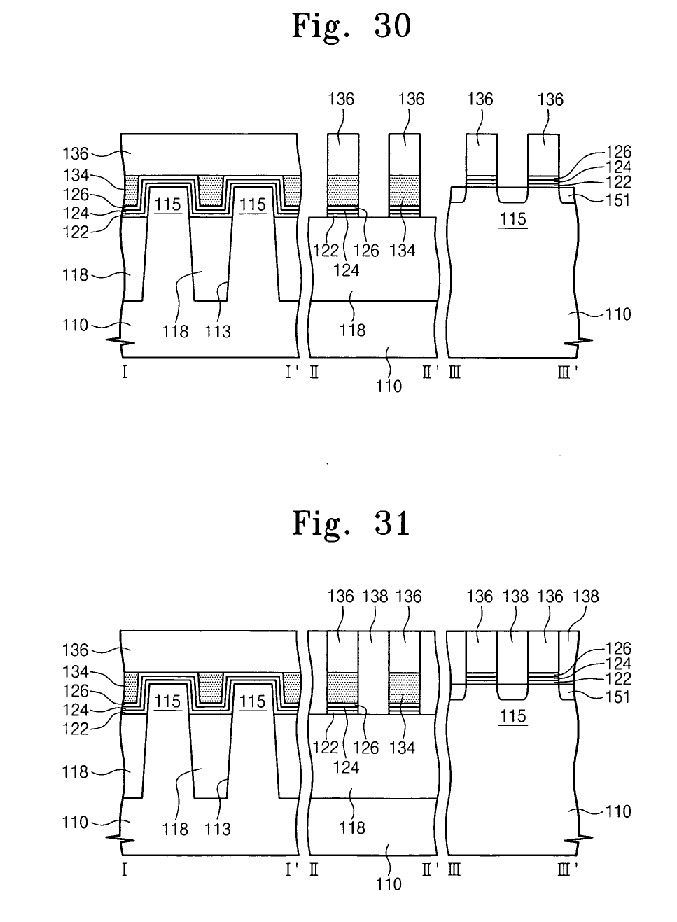

FIGS. 30-33 illustrate steps in a method of manufacturing the floating-trap memory device of FIG. 7 that are different than steps shown in FIGS. 10-15 and FIGS. 20-29. The steps in the method of FIGS. 30-33 are a variation of those described above in connection with FIGS. 25-29 and follow those steps except according to the following description. Referring to FIG. 30, following the steps of FIG. 25, the resistance layer 132, blocking layer 125, charge trapping layer 123 and tunneling layer 121 are etched through to expose the top surface of the STI region 118, using the photoresist pattern 136 as an etching mask, to form the “island” type resistance pattern 134 and “island” type configuration of the blocking layer 126, charge trapping layer 124 and tunneling layer 122.

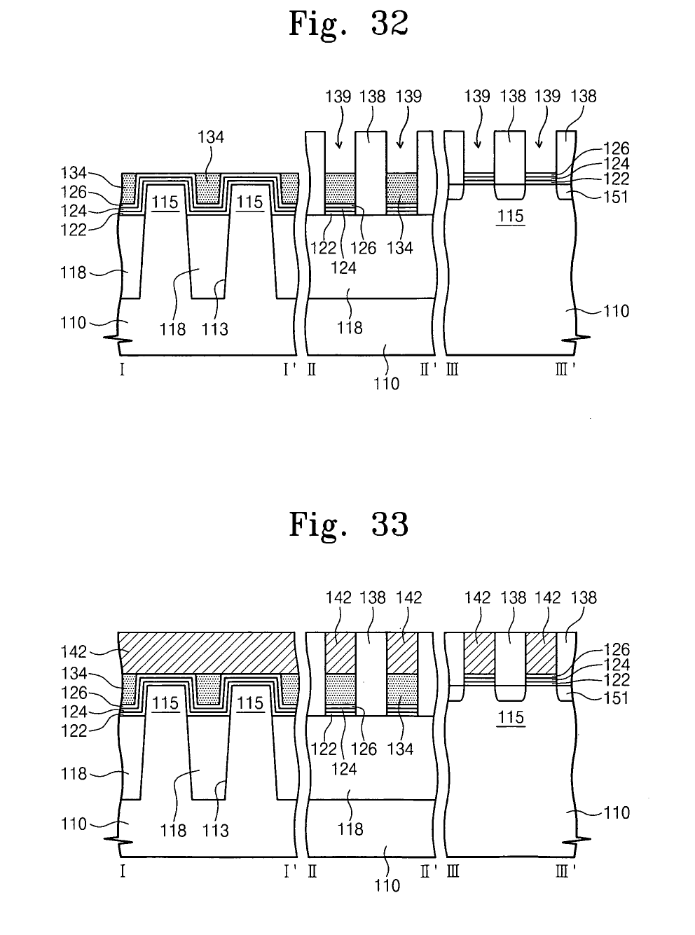

Referring to FIG. 31, next, the ILD pattern 138 is formed between the resistance patterns 134 and the blocking layer pattern 126, charge trapping pattern 124 and tunneling pattern 122 covered by the photoresist patterns 136. Referring to FIG. 32, next, the photoresist pattern 136 is removed, thus exposing the openings 139 over the “island” type resistance pattern 134, blocking pattern 126, charge trapping pattern 124 and tunneling pattern 122. Referring to FIG. 33, next, the conductive layer or line 142 is formed over the resistance pattern 134, blocking pattern 126, charge trapping pattern 124 and tunneling pattern 122 having the “island” configuration.

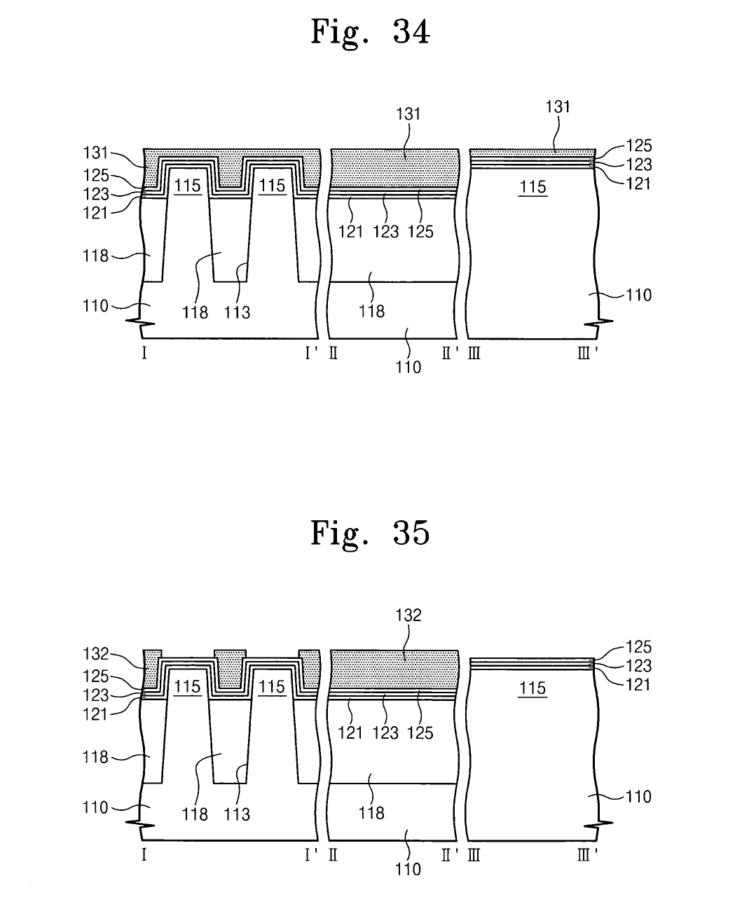

FIGS. 34-36 illustrate steps in a method of manufacturing the floating-trap memory device of FIG. 8 that are different than steps shown in FIGS. 10-15. Referring to FIG. 34, following the steps of FIG. 13, the resistance layer or pattern 132 is formed over the layers 121, 123 and 125. The top surface of the resistance pattern 132 is made to be higher than the top surface of the portion of the blocking layer 125 over the active regions 115. The resistance pattern 132 is formed over the STI layers 118 and the active regions 115. Referring to FIG. 35, the portion of the resistance pattern 132 over the active regions is removed, such as by photolithographic masking and etching.

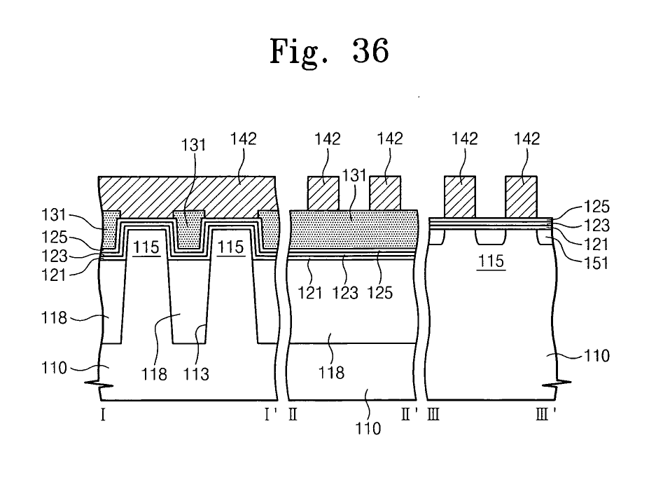

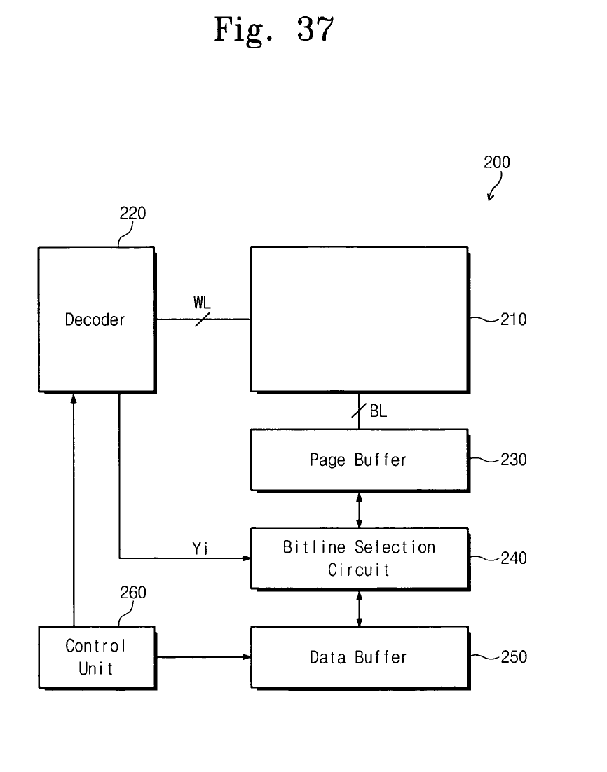

Referring to FIG. 36, next, the conductive line pattern 142 is formed over the structure.

FIG. 37 is a schematic block diagram of a nonvolatile memory device in accordance with some exemplary embodiments of the present invention.

Referring to FIG. 37, a semiconductor memory device 200 may include a cell array 210, a decoder 220, a page buffer 230, a bit line selection circuit 240, a data buffer 250 and a control unit 260. The semiconductor memory device 200 may be a NAND-type flash memory device.

The cell array 210 may include a plurality of memory blocks (not shown). Each memory block may be configured to include a plurality of pages (e.g., 32 pages, 64 pages, etc.), and each page may be configured to include a plurality of memory cells (e.g., 512 B, 2 KB, etc.), sharing one word line (WL). In a NAND-type flash memory device, an erase operation is performed on a memory block basis, and read and write operations are performed on a page basis.

Each page may store single-bit data or multi-bit data according to a mode signal (MOD).

The decoder 220 is connected to the cell array 210 through a word line and controlled by the control unit 260. The decoder 220 receives an address (ADDR) from a memory controller (not shown) and generates a selection signal Yi so as to select a word line or a bit line. The page buffer 230 is connected to the cell array 210 through a bit line.

The page buffer 230 stores data loaded from a buffer memory (not shown). The page buffer 230 loads one page data and the loaded data is simultaneously programmed to a selection page when a program operation is performed. When a read operation is performed, the page buffer 230 reads data from a selection page and temporarily stores the read data. Data stored in the page buffer 230 responds to a read enable signal (not shown) and transfers data to the buffer memory.

The bit line selection circuit 240 responds to the selection signal Yi and selects a bit line (BL). The data buffer 250 is an input/output buffer used for transmitting data between the memory controller and the flash memory device 200. The control unit 260 receives a control signal from the memory controller and controls an internal operation of the flash memory device 200.

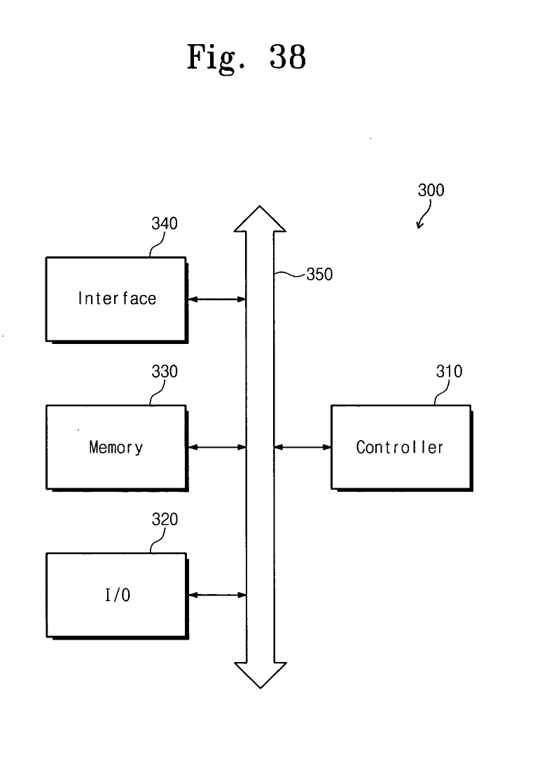

FIG. 38 contains a schematic block diagram of a system 300 including a semiconductor memory device in accordance with some exemplary embodiments of the present invention. The system 300 may be used in wireless communication device (e.g., PDA, a laptop computer, a portable computer, a web tablet, a wireless phone, a cell phone, etc.), or in a device that can transmit and/or receive information in a wireless environment.

The system 300 may include a controller 310, an input/output device 320 such as a key pad, key board or a display, a memory 330, and a wireless interface 340. The controller 310 may include at least one microprocessor, digital signal processor, microcontroller or the like. The memory 330 may be used for storing an instruction code executed by the controller 310. The memory 330 may also be used for storing user data. The memory 330 includes a nonvolatile memory device in accordance with some exemplary embodiments of the present invention. The memory 330 may also include various kinds of memories and a random access volatile memory.

The system 300 may use a wireless interface 340 to transfer data to a wireless communication network that communicates by RF signal or to receive data from the wireless communication network that communicates by RF signal. For example, the wireless interface 340 may include an antenna, a wireless transceiver and so on.

The system 300 according to some exemplary embodiments of the present invention may be used in a communication protocol such as a third generation communication system (e.g., CDMA, GSM, NADC, E-TDMA, WCDMA or CDMA3000).

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor memory device, comprising:
a substrate;
an isolation region formed in the substrate;
an active region formed in the substrate adjacent to the isolation region;
a tunneling layer on the active region and the isolation region;
a charge trapping layer on the tunneling layer;
a blocking layer on the charge trapping layer; and
a resistance layer on the blocking layer over the isolation region.

2. The semiconductor memory device of claim 1, wherein the resistance layer comprises polysilicon.

3. The semiconductor memory device of claim 1, wherein the resistance layer comprises a substantially flat top surface.

4. The semiconductor memory device of claim 1, wherein the resistance layer comprises a substantially curved bottom surface.

5. The semiconductor memory device of claim 1, wherein the resistance layer is an island type with multiple resistance layers over the isolation region.

6. The semiconductor memory device of claim 1, wherein a top surface of resistance layer has a height higher than a height of the blocking layer.

7. The semiconductor memory device of claim 1, wherein the resistance layer is a non-metal resistance layer.

8-14. (canceled)
